(19) United States
(12) Patent Application Publication
(10) Pub. No.: US 2026/0005098 A1
(43) Pub. Date: Jan. 1, 2026

(54) BACKSIDE POWER DELIVERY NETWORK HEAT DISSIPATION

(71) Applicant: International Business Machines Corporation, Armonk, NY (US)

(72) Inventors: HUIMEI ZHOU, Albany, NY (US); Oleg Gluschenkov, Tannersville, NY (US); Ruilong Xie, Niskayuna, NY (US)

(21) Appl. No.: 18/757,963

(22) Filed: Jun. 28, 2024

(51) Int. Cl. H01L 23/373; H01L 23/29; H01L 23/528; H01L 23/532

(52) U.S. Cl. CPC H01L 23/3736; H01L 23/291; H01L 23/5286; H01L 23/53228; H01L 23/53276

(57) ABSTRACT

A structure comprising: a back-end-of-line portion on top of a device, wherein the device comprises a hot circuit and a cold circuit; a wafer on top of the back-end-of-line portion; a backside power distribution network on a side of the wafer; a thermal sink underneath the device and the backside power distribution network; and one or more scaling balls underneath the thermal sink and on top of a laminate.

### BACKGROUND

The invention relates generally to the field of backside power delivery networks, and more particularly to heat dissipation.

A power delivery network is designed to provide power supply and reference voltage to active devices on a die. Traditionally, the power delivery network is realized as a network of low-resistive metal wires fabricated through back-end-of-line (BEOL) processing on a frontside of a wafer. The power delivery network shares this space with a signal network, i.e., interconnects designed to transport a signal.

Backside power delivery networks (BSPDN) decouple the power delivery network from the signal network by moving a power distribution network to a backside of a silicon wafer, enabling direct power delivery to standard cells through wider, less resistive metal lines, without electrons needing to travel through the BEOL stack. This approach benefits voltage (IR) drop, improves power delivery performance, reduces BEOL routing congestion, and allows for standard cell height scaling.

### SUMMARY

Embodiments of the invention disclose a structure comprising: a back-end-of-line (BEOL) portion on top of a device, wherein the device comprises a hot circuit and a cold circuit; a wafer on top of BEOL; a backside power distribution network on a side of the wafer; a thermal sink underneath the device and the backside power distribution network; and one or more scaling balls underneath the thermal sink and on top of a laminate.

Embodiments of the invention disclose a package comprising: A structure comprising: a back-end-of-line (BEOL) portion on top of a device region, wherein the device region comprises a hot circuit and a cold circuit; a wafer on top of BEOL; a backside power distribution network (BSPDN) on a side of the wafer; a thermal sink underneath the device region, wherein: the thermal sink comprises one or more connecting structures encapsulated by an insulator; and the insulator is encapsulated by a thermally conductive material; and one or more scaling balls underneath the thermal sink and on top of a laminate.

Embodiments of the invention disclose a package comprising: a back-end-of-line portion on top of a front-end-of-line portion, wherein the front-end-of-line portion is bonded on top of a thermal sink, wherein the thermal sink is bonded on top of one or more scaling balls, wherein the one or more scaling balls are bonded on top of a laminate.

### BRIEF DESCRIPTION OF THE DRAWINGS

Figure (i.e., FIG. 1A is an illustration of a die-on-die assembly, according to one embodiment of the present disclosure;

FIG. 1B is an illustration of a die-on-die assembly with heat distribution, in accordance with an embodiment of the invention;

FIG. 2A is an illustration of a second die-on-die assembly, in accordance with an embodiment of the invention;

FIG. 2B is an illustration of the second die-on-die assembly with heat distribution, in accordance with an embodiment of the invention; and

FIG. 3 is an illustration of a heat capacitor, in accordance with an embodiment of the invention.

### DETAILED DESCRIPTION

Heat dissipation is a critical issue within circuit design. Poor heat dissipation in a circuit board, die, or package has severe negative effects on component functionality and reliability. These effects are exacerbated due to nonuniform heating within the die or package. Traditionally, a high-end die dissipates approximating 300 watt (W) over 750 mm² or 40 W/cm², where a steady state is achieved within ˜μs vertically and a second laterally. Moreover, a temperature drop across the entire BEOL stack is <1 kelvin (K), where the die temperature increase is due to thermal resistance between the die and an external environment. Certain circuits dissipate a higher power density than average dies, but these circuits are limited by a finite size. For example, an array of fast ring oscillators (ROs) can dissipate 20-30 kW/cm² over several um². In this example, a quasi-steady state is achieved within ˜100 nanoseconds (ns) and local temperatures rise and plateau at ˜10 K above the package. Additionally, some devices (e.g., phase-change memory (PCRAM)) require high power dissipation that cause local temperatures to rise within ˜10 ns followed by a cool down period due to heat diffusion.

Present state-of-the-art die and package assembly includes a thinned down crystalline silicon (c-Si) die (30-60 um in thickness) on which logic transistors reside followed by >15 levels of metallic interconnects. The high thermal conductivity of c-Si (e.g., 1.3 W/cm-K) and copper (Cu) metal (e.g., 4 W/cm-K) reduce an intensity of hot spots on intermediate temporal and spatial scales. Modern BSPDN architecture removes the highly thermally conducting Si substrate from underneath the heat source (e.g., transistors) and places the substrate above the BEOL interconnects, increasing the intensity of hot spots on the intermediate scale.

Embodiments of the invention propose a structure within an BSPDN architecture to improve thermal dissipation at the intermediate temporal (˜100 ns to a μs) and spatial (1 μm to 10 μm) scale. Embodiments of the invention reduce the BSPDN thermal resistance with a specialized BSPDN-specific interlayer dielectric (ILD), where power distribution networks do not require low electrical capacitance interconnects. Embodiments of the invention attach high thermal capacitance material (e.g. matching or exceeding the thermal capacitance of 10 mm of Si) for effective heat equalization at the intermediate temporal and special scale. Some embodiments of the invention recognize that thermal resistance of a front BEOL interconnects at 0.001 K-cm²/W and is defined by a pattern density and an overall thickness of via levels with contribution from ILD of less than 5%. Some embodiments of the invention recognize that thermal conductivity of Cu wires and vias scale with a measured electrical conductivity of Cu, where the thermal conductivity is substantially lower for small vias/wires at ˜ 1 W/cm-K or below. Some embodiments of the invention recognize that BEOL via pattern density is around 3% and the via level effective thermal conductivity is ˜0.03 W/cm-K. Some embodiments of the invention recognize that the ILD has a low thermal conductivity of below 0.01 W/cm-K (oxide) and typically 0.002 W/cm-K, contributing to thermal conduction of at least less than 25% (typically less than 5%). Some embodiments of the invention recognize that areal thermal resistance of 10 30 nm-thick via levels is 300 nm/0.032 W/cm-K=˜0.001 K-cm²/W. Some embodiments of the invention recognize that areal thermal resistance of ˜10 μm of Si substrate is ˜0.001 K-cm²/W and areal thermal capacitance of 1.73 J/K-cm³×10 μm=0.00173 J/K-cm².

Some embodiments of the invention recognize that a BSPDN network is relatively thin as compared to a silicon (Si) substrate. Some embodiments of the invention recognize that, similar to BSPDN, thermal resistance is defined by via levels with a small pattern density, where the contribution of a BSPDN ILD to thermal resistance is ˜25% due to a ILD formed of silicon dioxide (SiO₂). Embodiments of the present invention reduce a BSPDN thermal resistance by ˜20% with a specialized BSPDN-specific ILD and an attached high thermal capacitance material (e.g. matching or exceeding a thermal capacitance of 10 μm of Si) for effective heat equalization at intermediate temporal and special scales.

Embodiments of the invention disclose a package comprising: a back-end-of-line portion on top of a device region, wherein the device region comprises an active component and an inactive component; a thermal sink underneath the device region; and one or more scaling balls underneath the thermal sink and on top of a laminate.

Embodiments of the invention disclose a package comprising: a back-end-of-line portion on top of a device region, wherein the device region comprises an active component and an inactive component; a thermal sink underneath the device region, wherein: the thermal sink comprises one or more connecting structures fully encapsulated by an insulator; and the insulator is fully encapsulated by a thermally conductive material; and one or more scaling balls underneath the thermal sink and on top of a laminate.

Embodiments of the invention disclose a package comprising: a back-end-of-line portion on top of a front-end-of-line portion, wherein the front-end-of-line portion is bonded on top of a thermal sink, wherein the thermal sink is bonded on top of one or more scaling balls, wherein the one or more scaling balls are bonded on top of a laminate.

Implementation of embodiments of the invention may take a variety of forms, and exemplary implementation details are discussed subsequently with reference to the Figures.

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” or “underneath” or “back of” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a”, “an”, and “the” are intended to include the plural forms as well, unless the context clearly indicates otherwise. It will be further understood that the terms “comprises”, “comprising” “includes”, and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently redescribed.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

In general, the various processes used to form a semiconductor chip fall into four general categories, namely, film deposition, removal/etching, semiconductor doping, and patterning/lithography.

Deposition is any process that grows, coats, or otherwise transfers a material onto the wafer. Available technologies include but are not limited to physical vapor deposition (“PVD”), chemical vapor deposition (“CVD”), electrochemical deposition (“ECD”), molecular beam epitaxy (“MBE”) and more recently, atomic layer deposition (“ALD”) among others. Another deposition technology is plasma enhanced chemical vapor deposition (“PECVD”), which is a process that uses the energy within the plasma to induce reactions at the wafer surface that would otherwise require higher temperatures associated with conventional CVD. Energetic ion bombardment during PECVD deposition can also improve the film's electrical and mechanical properties.

Removal is any process such as etching or chemical-mechanical planarization (“CMP”) that removes material from the wafer. Examples of etch processes include either wet (e.g., chemical) or dry etch processes. One example of a removal process or dry etch process is ion beam etching (“IBE”). In general, IBE (or milling) refers to a dry plasma etch method that utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry etch process is reactive ion etching (“RIE”). In general, RIE uses chemically reactive plasma to remove material deposited on wafers. High-energy ions from the RIE plasma attack the wafer surface and react with the surface material(s) to remove the surface material(s).

Semiconductor doping is the modification of electrical properties of a material by doping, for example, transistor sources and drains, generally by diffusion and/or by ion implantation. These doping processes may be followed by furnace annealing or by rapid thermal annealing (RTA). Annealing serves to activate the implanted dopants. Films of both conductors (e.g., polysilicon, aluminum, copper, etc.) and insulators (e.g., various forms of silicon dioxide, silicon nitride, etc.) may be used to connect and isolate transistors and their components. Selective doping of various regions of the semiconductor substrate allows the conductivity of the substrate to be changed with the application of voltage. By creating structures of these various components, billions of transistors can be built and wired together to form the complex circuitry of a modern microelectronic device.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. The pattern created by lithography or photolithography typically are used to define or protect selected surfaces and portions of the semiconductor structure during subsequent etch processes.

The invention will now be described in detail with reference to the Figures.

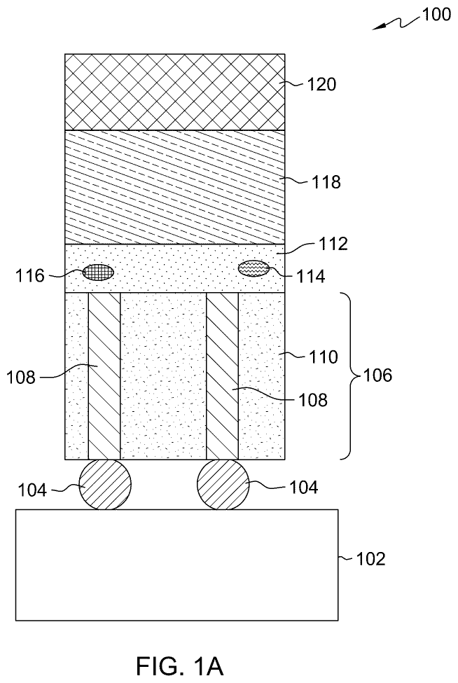

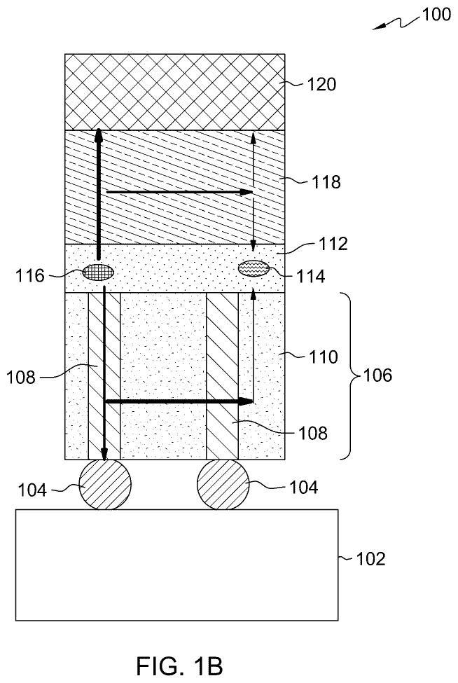

FIG. 1 illustrates a cross-sectional view of exemplary die-on-die assembly 100, which may be stacked in a package with enhanced thermal dissipation performance, according to one embodiment of the present disclosure.

The die-on-die assembly (i.e., structure) 100 includes a laminate 102 underneath a scaling balls 104, formed at a bottom of a heat capacitor 106. The scaling balls 104 may be electrically connected to the heat capacitor 106. The scaling balls 104 may be copper pillars or solder balls (see FIG. 1).

In detail, the heat capacitor 106 is a thermal sink for a device region 112, wherein heat capacitor 106 is below device region 112 and above scaling balls 104. The heat capacitor 106 is configured to be coupled to the device region 112, such that heat generated by the device region 112 can propagate through the heat capacitor 106. The heat capacitor 106 may include one or more connecting structures 108 fully encapsulated by an insulator 110. The heat capacitor 106 may include one or more connecting structures 108 encapsulated by the insulator 110, wherein the insulator 110 does not encapsulate on the top and the bottom of connecting structures 108. The connecting structures 108 may be formed of copper (Cu). In an embodiment, thermal conductivity of Cu wires and Cu vias scales with a measured electrical conductivity of Cu, wherein the thermal conductivity is substantially lower for small vias/wires at ˜1 W/cm-K or below. The connecting structures 108 improves thermal transition. The insulator 110 has high thermal conductivity and is electrically insulating. The insulator 110 may be formed of diamond, aluminum nitride, or boron nitride.

The device region 112 may be a front-end-of-line (FEOL) portion and includes one or more inactive sections 114 (e.g., cold circuit or device) and one or more active sections 116 (e.g., hot circuit or device) that are configured to provide one or more electrical device components, such as switch field-effect transistors (FETs), diodes, capacitors, resistors, and/or inductors (not shown), wherein the one or more inactive sections 114 produce less heat (i.e., colder) than the one or more active sections 116 (e.g., hotter). In an embodiment, the inactive sections 114 and active sections 116 may include one or more of gallium arsenide (GaAs), indium phosphide (InP), gallium nitride (GaN), gallium phosphide (GaP), gallium carbon (GaC), gallium, indium gallium arsenide (InGaAs), indium gallium nitride (InGaN), indium gallium phosphide (InGaP), indium gallium carbide (InGaC). The device region 112 is vertically below a back-end-of-line (BEOL) 118. The BEOL 118 may be configured to connect the device region 112 to external components. The BEOL 118 is vertically below and bonded to wafer 120. The wafer 120 may be a temporary structure utilized in the handling of the die-on-die assembly 100. The wafer 120 may be formed of, for example, glass, quartz, or silicon. In an embodiment, a backside power distribution network (BSPDN) is bonded between device region 112 and heat capacitor 106. In another embodiment, the BSPDN is bonded on the backside of the wafer 120.

In an embodiment, the device region 112 is formed and attached to the bottom of BEOL 118 with a middle-of-line (MOL) layer that separates transistor and interconnect pieces using a series of contact structures. The MOL layer may be formed of tungsten or cobalt. Then, wafer 120 is bonded on top of BEOL 118. Then, heat capacitor 106 is bonded or deposited below device region 112. In an embodiment, the BSPDN is bonded between device region 112 and heat capacitor 106, where heat capacitor 106 is comprised of the insulator 110. Responsively, one or more vertical openings are removed from heat capacitor 106 and the openings are filled with a metal, forming connecting structures 108. Then, a suitable combination of patterning and material removal processes are performed to form bottom metal contact holes or vias. Then, scaling balls 104 are bonded to the formed vias.

FIG. 1B illustrates a cross-sectional view of exemplary die-on-die assembly 100 with heat distribution, according to one embodiment of the present disclosure.

Thermal generation and dissipation may commence from the device region 112 (e.g., FEOL) and internalized components (e.g., active sections 116). In an embodiment, heat generated from active section 116 is conducted vertically up to the BEOL 118 and vertically down to the connecting structures 108, where the heat conducted to the BEOL 118 is greater (e.g., higher thermal conductivity) than the heat conducted to the connecting structures 108. In an embodiment, within the BEOL 118, heat is conducted from active section 116 vertically to wafer 120 and laterally through the BEOL 118. In an embodiment, heat dissipated laterally is subsequently conducted vertically to wafer 120 and to inactive section 114 within device region 112. In another embodiment, the heat distributed laterally is conducted equally to wafer 120 and inactive section 114. In an embodiment, the laterally conducted heat is less than the heat conducted vertically from active section 116.

In an embodiment, heat conducted vertically down to the connecting structures 108 and subsequently conducted to scaling balls 104 and laterally to an adjacent connecting structures 108. Heat conducted to the adjacent connecting structures 108 is conducted vertically up to inactive section 114.

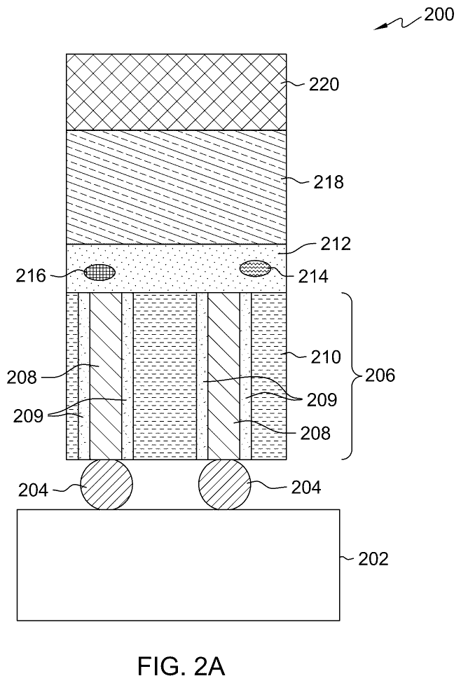

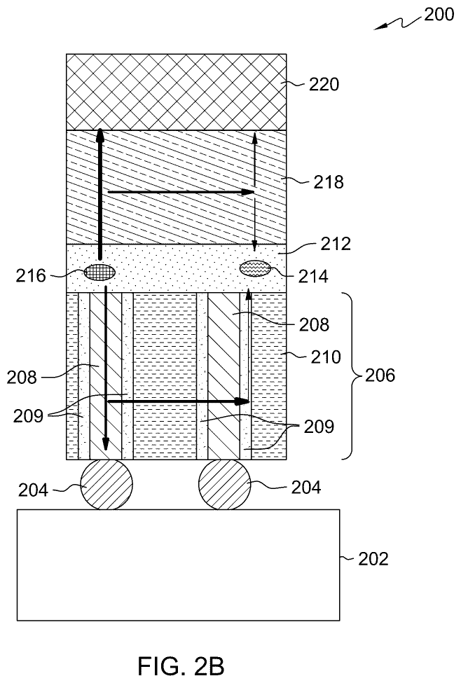

FIG. 2A illustrates a cross-sectional view of exemplary die-on-die assembly 200, according to one embodiment of the present disclosure.

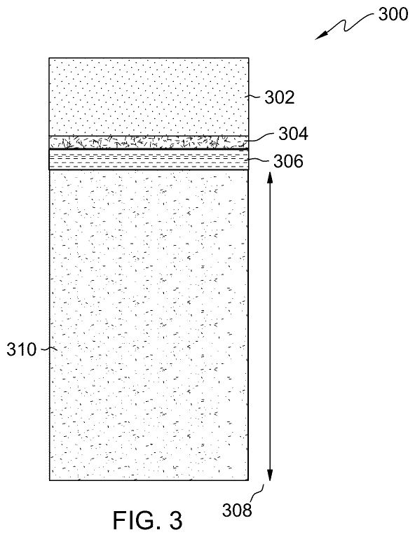

The die-on-die assembly 200 includes a laminate 202 underneath a scaling balls 204, formed at a bottom of a heat capacitor 206. The scaling balls 204 may be electrically connected to the heat capacitor 206. The scaling balls 204 may be copper pillars or solder balls (see FIG. 3).

In detail, the heat capacitor 206 is a thermal sink for a device region 212, wherein heat capacitor 206 is underneath device region 212 and above scaling balls 204. The heat capacitor 206 may include one or more connecting structures 208 fully encapsulated by an insulator 209, wherein the insulator 209 isolates different power distributors. The heat capacitor 206 may include one or more connecting structures 208 encapsulated by the insulator 209, wherein the insulator 209 does not encapsulate on the top and the bottom of connecting structures 208. The one or more connecting structures 208 may be formed of a metal. The insulator 209 may be formed of diamond, aluminum nitride (AlN), or boron nitride (BN). In an embodiment, insulator 209 is formed of AIN which has high thermal conductivity, high resistivity, corrosion resistance, a large piezoelectric coefficient (e.g., 5.1 pmV⁻¹), low dielectric loss, wide-band gap semiconductor (e.g., 6.3 eV). The insulator 209 may be encapsulated by material 210, which has high thermal conductivity properties. The material 210 may be formed of graphene. In an embodiment, additional high thermal conductivity material is located between heat capacitor 206 and scaling balls 204, where the high thermal conductivity material has a thermal conductivity greater than 100 Wm/K and a dielectric constant <5.

The device region 212 may be a front-end-of-line (FEOL) portion and includes one or more inactive sections 214 and one or more active sections 216 that are configured to provide one or more electrical device components, such as switch field-effect transistors (FETs), diodes, capacitors, resistors, and/or inductors (not shown), wherein the one or more inactive sections 214 produce less heat than the one or more active sections 216. The device region 212 is underneath a back-end-of-line (BEOL) 218. The BEOL 218 may be configured to connect the device region 212 to external components. The BEOL 218 is underneath and bonded to wafer 220. The wafer 220 may be formed of, for example, glass, quartz, or silicon. In an embodiment, a backside power distribution network (BSPDN) is bonded between device region 212 and heat capacitor 206. In another embodiment, the BSPDN is bonded on the backside of the wafer 220.

In an embodiment, the device region 212 is formed and attached to the bottom of BEOL 218 with a MOL layer that separates transistor and interconnect pieces using a series of contact structures. The MOL layer may be formed of tungsten or cobalt. Then, wafer 220 is bonded on top of BEOL 218. Then, heat capacitor 206 is bonded or deposited below device region 212. In an embodiment, a backside power distribution network (BSPDN) is bonded between device region 212 and heat capacitor 206, where heat capacitor 206 is comprised of the material 210. Responsively, one or more vertical openings are removed from the material 210 and the openings are filled with an insulator, forming the insulator 209. Then, one or more vertical openings are removed from the insulator 209 and the openings are filled with a metal, forming connecting structures 208. Then, a suitable combination of patterning and material removal processes are performed to form bottom metal contact holes or vias. Then, the scaling balls 204 are bonded to the formed vias.

FIG. 2B illustrates a cross-sectional view of exemplary die-on-die assembly 200 with heat distribution, according to one embodiment of the present disclosure.

Thermal generation and dissipation may commence from the device region 212 (e.g., FEOL) and internalized components (e.g., active sections 216). In an embodiment, heat generated from active section 216 is conducted vertically up to the BEOL 218 and vertically down to the connecting structures 208, where the heat conducted to the BEOL 218 is greater than the heat conducted to the connecting structures 208. In an embodiment, within the BEOL 218, heat is conducted from active section 216 vertically to wafer 220 and laterally through the BEOL 218. In an embodiment, heat dissipated laterally is subsequently conducted vertically to wafer 220. In an embodiment, the laterally conducted heat is less than the heat conducted vertically from active section 216. In an embodiment, heat conducted vertically down to the connecting structures 208 and subsequently conducted to the scaling balls 204 and laterally to an adjacent connecting structures 208. Heat conducted to the adjacent connecting structures 208 is conducted vertically up to inactive section 214, where the heat conducted vertically is less than the heat conducted laterally within heat capacitor 206.

FIG. 3 illustrates a cross-sectional view of exemplary heat capacitor structure 300, which may be stacked within a package, according to one embodiment of the present disclosure. Heat capacitor structure 300 includes heat capacitor 310 (e.g., heat capacitor 106, heat capacitor 206), a thermal sink for device 302 (e.g., device region 112). Heat capacitor 310 may be defined by a vertical thickness 308 that represents a thermal diffusion length. In an embodiment, thickness 308 is defined by an equation: 2\sqrt{α·time}, wherein α=k/Cₚρ, k is thermal conductivity, ρ is electrical resistivity, and Cₚ is a heat capacity at a constant pressure. In an exemplary embodiment, the heat capacitor 310 may have a (vertical) thickness although other thicknesses above or below this range may be used as desired for a particular application. In an embodiment, heat capacitor 310 is underneath a backside metal layer 306. Backside metal layer 306 (e.g., BSPDN) may be formed of a metal such as tungsten, tungsten carbide, copper, titanium, titanium nitride, and ruthenium. Backside metal layer 306 connects with a layer 304. Layer 304 may be formed of AlN. Layer 304 is below device 302 and on top of the backside metal layer 306. In an embodiment, the layer 304 has a thermal conductivity greater than 100 W·m⁻¹·K⁻¹ and a dielectric constant of less than 5.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure comprising:
a back-end-of-line (BEOL) portion on top of a device, wherein the device comprises a hot circuit and a cold circuit;
a wafer on top of BEOL;
a backside power distribution network (BSPDN) on a side of the wafer;
a thermal sink underneath the device and the BSPDN; and
one or more scaling balls underneath the thermal sink and on top of a laminate.

2. The structure of claim 1, wherein the thermal sink comprises:
one or more connecting structures encapsulated by an insulator.

3. The structure of claim 2, wherein the one or more connecting structures are formed of copper.

4. The structure of claim 2, wherein the insulator is formed of aluminum nitride.

5. The structure of claim 1, wherein the device is a front-end-of-line (FEOL) portion.

6. The structure of claim 2, wherein the insulator is formed of diamond.

7. The structure of claim 2, wherein the insulator is formed of boron nitride.

8. The structure of claim 1, wherein the one or more scaling balls are formed of aluminum.

9. The structure of claim 1, further comprising:
a layer of aluminum nitride between the device region and the thermal sink.

10. The structure of claim 9, further comprising:
a backside metal layer underneath the layer of aluminum nitride between the device region and the thermal sink.

11. The structure of claim 10, wherein the backside metal layer is tungsten.

12. The structure of claim 10, wherein the backside metal layer is copper.

13. The structure of claim 10, wherein the layer has a dielectric constant of less than 5.

14. A structure comprising:
a back-end-of-line (BEOL) portion on top of a device region, wherein the device region comprises a hot circuit and a cold circuit;
a wafer on top of BEOL;
a backside power distribution network (BSPDN) on a side of the wafer;
a thermal sink underneath the device region, wherein:
the thermal sink comprises one or more connecting structures encapsulated by an insulator; and
the insulator is encapsulated by a thermally conductive material; and
one or more scaling balls underneath the thermal sink and on top of a laminate.

15. The structure of claim 14, wherein the thermally conductive material is graphene.

16. The structure of claim 14, wherein the insulator is formed of aluminum nitride.

17. The structure of claim 14, wherein the one or more connecting structures are formed of copper.

18. The structure of claim 14, further comprising:
a layer of aluminum nitride between the device region and the thermal sink.

19. The structure of claim 18, further comprising:
a backside metal layer underneath the layer of aluminum nitride between the device region and the thermal sink.

20. A structure comprising:
a back-end-of-line (BEOL) portion on top of a front-end-of-line (FEOL) portion, wherein the FEOL is bonded on top of a thermal sink, wherein the thermal sink is bonded on top of one or more scaling balls, wherein the one or more scaling balls are bonded on top of a laminate.
